(19) United States
(12) Patent Application Publication
(10) Pub. No.: US 2001/0043989 A1
(43) Pub. Date: Nov. 22, 2001

(54) Film forming apparatus and film forming method

(76) Inventors: Masami Akimoto, Kumamoto-Ken (JP); Yoichi Deguchi, Tokyo-To (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 09/855,806

(22) Filed: May 16, 2001

(30) Foreign Application Priority Data
May 18, 2000 (JP) 2000-146314

(51) Int. Cl. C23C 16/00

(52) U.S. Cl. 427/299; 118/715; 156/345

(57) ABSTRACT

In a method of fabricating a conductive layer in an insulating film using a damascene process, a copper film is formed on a wafer in a copper formation processing chamber of a film forming apparatus, and then CMP processing is performed for the wafer in a CMP processing chamber. After the CMP processing, the wafer is subjected to cleaning processing in a cleaning chamber, and dried under reduced pressure in a reduced-pressure drying chamber. The wafer which has been subjected to the reduced-pressure drying processing is carried into a CVD unit under reduced pressure, thereby securely suppressing natural oxidization of the copper film formed on the wafer. This can prevent the oxidization of a conductive material as much as possible.

### BACKGROUND OF THE INVENTION

1. Field of the Invention

The present invention relates to a film forming apparatus and a film forming method for forming an insulating film, for example, on an oxidization-prone film.

2. Description of the Related Art

As the super LSI is highly integrated, it becomes more important to make wiring formed on a semiconductor wafer (hereafter, referred only to as “a wafer” ) fine and to flatten a layer insulating film. A technology for realizing the fining of the wiring and flattening of the layer insulating film, there is a well-known wiring technique called damascene method.

In the damascene method, a predetermined groove is previously formed in the layer insulting film, a conductive wiring material such as Al, Cu or the like is embedded inside the groove by a sputtering method or a CVD method, and the wiring material accumulated outside the groove is removed by a CMP (chemical mechanical polishing) technology or the like, thereby forming a wiring. Through cleaning and drying steps after the CMP processing, an insulating film such as silicon nitride is further formed by the CVD method to prevent natural oxidization of the wiring material. In the insulating film formation by the CVD method, the wafer is caused to wait in a load-lock chamber in a vacuum or under an inert gas atmosphere such as N₂ before the wafer is carried into the CVD processing chamber to suppress the growing of natural oxide film of the wiring material.

However, the wiring material is exposed to the atmospheric air during the fabrication process from the CMP processing until the insulating film being formed, for example, during the drying step and the like after the cleaning, bringing about a disadvantage that the wiring material is prone to oxidization.

### SUMMARY OF THE INVENTION

An object of the present invention is to provide a film forming apparatus and a film forming method capable of preventing oxidization of a material as much as possible.

Another object of the present invention is to provide a film forming apparatus and a film forming method capable of preventing oxidization of a conductive material as much as possible in a method of fabricating a conductive layer in an insulating film using, for example, a damascene process.

Still another object of the present invention is to prevent oxidization of an oxidization-prone film as much as possible in a film forming apparatus and a film forming method for forming a film, for example, on an oxidization-prone film using a CVD method.

In order to solve the aforementioned disadvantage, a film forming apparatus according to a first aspect of the present invention comprises: a drying chamber for drying a cleaned substrate under a reduced pressure; a film forming chamber for forming a film on the substrate by a CVD method under a reduced pressure; and a transfer path for transferring the substrate under a reduced pressure from the drying chamber to the film forming chamber.

A film forming method according to a second aspect of the present invention comprises the steps of: drying a cleaned substrate under a reduced pressure; transferring the substrate with the reduced-pressure state kept after the reduced-pressure drying; and forming a film on the substrate by a CVD method under a reduced pressure after the transfer.

An apparatus according to a third aspect of the present invention comprises: a first substrate carrier for transferring a substrate in an atmospheric air; a second substrate carrier provided almost perpendicular to the first substrate carrier for transferring the substrate in the atmospheric air; and a processing chamber capable of delivering and receiving the substrate to/from at least one of the first substrate carrier and the second substrate carrier, for processing the substrate under a reduced pressure.

An apparatus according to a fourth aspect of the present invention comprises: a first substrate carrier for transferring a substrate in an atmospheric air; a second substrate carrier for transferring the substrate under a reduced pressure; and a third substrate carrier for transferring the substrate between the first substrate carrier and the second substrate carrier.

According to the present invention, for example, the drying step is performed under a reduced pressure and the substrate is transferred into the film forming chamber with the reduced pressure state kept, whereby, for example, in the case in which an oxidization-prone film such as copper is formed on the substrate, natural oxidization of the oxidization-prone film can be securely suppressed.

Now, a case of an apparatus having a configuration in which a substrate, after processed in a drying chamber and exposed to the atmospheric air, is carried into a film forming chamber through a reduced-pressure processing chamber is compared to the present invention. The former case requires that the pressure inside the reduced-pressure processing chamber is reduced from the atmospheric pressure. In the present invention, however, it is unnecessary to reduce the pressure from the atmospheric pressure along the transfer path of the substrate from the drying chamber to the film forming chamber, resulting in extremely high energy efficiency.

These objects and still other objects and advantages of the present invention will become apparent upon reading the following specification when taken in conjunction with the accompanying drawings.

### BRIEF DESCRIPTION OF THE DRAWINGS

FIG. 1 is a plan view of a film forming apparatus according to an embodiment of the present invention;

FIG. 2 is a perspective view of reduced-pressure drying chambers constituting part of the film forming apparatus shown in FIG. 1;

FIG. 3 is a chart for explaining fabrication process of a semiconductor element which is fabricated through a dual damascene process;

FIGS. 4A to 4E are sectional views (first part) of the semiconductor element in the respective fabrication processing steps explained in FIG. 3;

FIGS. 5A to 5E are sectional views (second part) of the semiconductor element in the respective fabrication processing steps explained in FIG. 3;

FIG. 6 is a sectional view (third part.) of the semiconductor element in the respective fabrication processing step explained in FIG. 3;

FIG. 7 is a schematic sectional view of a CVD unit; and

FIG. 8 is a plan view of a film forming apparatus according to another embodiment of the present invention.

### DETAILED DESCRIPTION OF THE PREFERRED EMBODIMENT

Hereinafter, preferred embodiments of the present invention will be described with reference to the drawings.

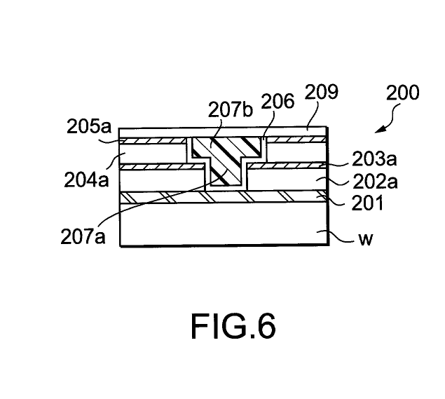

This embodiment is explained taking an example of a fabrication method of a semiconductor element with a structure shown in FIG. 6 which is fabricated through a dual damascene process. In a semiconductor element 200 in this embodiment, as shown in FIG. 6, a lower layer wiring 201 is disposed on a semiconductor wafer W (a wafer, hereinafter) as a substrate, and the lower layer wiring 201a is formed thereon with a layer insulating film composed of laminated films of a first organic insulating film 202a, a first inorganic insulating film 203a, a second organic insulating film 204a and a second inorganic insulating film 205a. The layer insulating film is formed therein with a wiring 207b made of, for example, copper, as a conductive material and a connecting plug 207a made of copper for connecting the lower layer wiring 201 and the wiring 207b. Between the layer insulating film, and the wiring 207b and the connecting plug 207a, for example, titanium nitride is formed as a side wall protecting film 206 to prevent copper from diffusing into the layer insulating film. Further, a silicon nitride film 209 is formed on the surface of the semiconductor element 200 to prevent natural oxidization of the wiring.

An organic insulating film with a low permittivity characteristic of a permittivity of three or less can be used for the organic insulating films 202a and 204a. It is possible to use, for example, an organic polymer such as PAE-2 (Shumacher Inc.), HSG-R7 (Hitachi Chemical Co., Ltd.), FLARE (Allied Signal Inc.), BCB (Dow Chemical Ltd.), SILK (Dow Chemical Ltd.) and Speed Film (W. L. Gore & Associates, Inc.). SILK (Dow Chemical Ltd.) is used in this embodiment. Further, a silicon nitride film is used for the inorganic insulating film 203a, and a silicon oxide film for the inorganic insulating film 205a in this embodiment, but, not limited to these materials, for example, an inorganic SOG film may be used. A film having strength enough for CMP processing in the dual damascene process is suitable as the inorganic insulating film 205a.

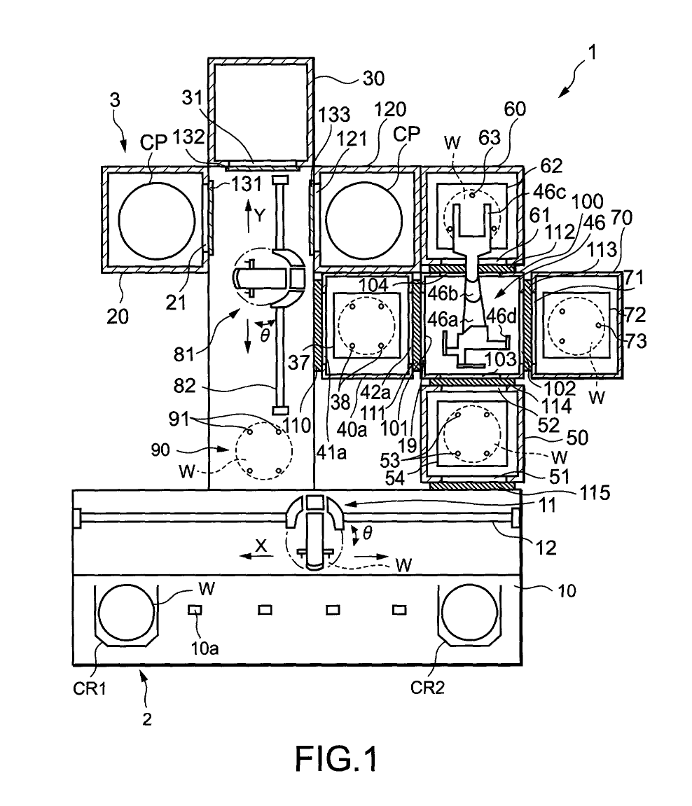

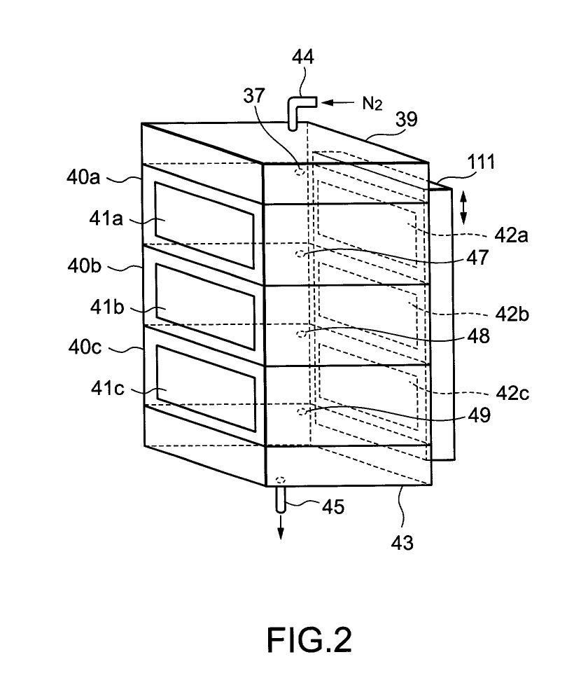

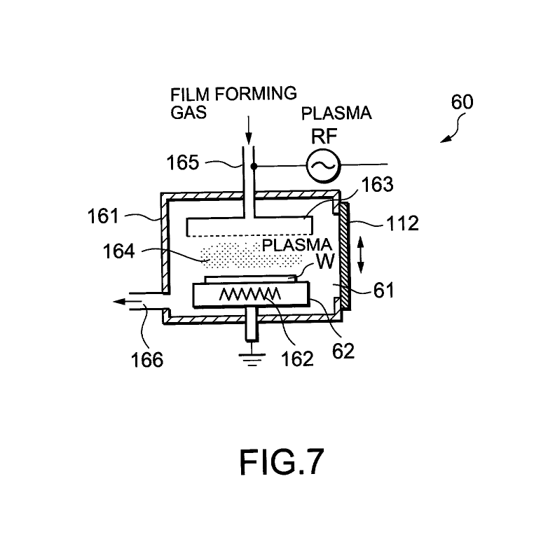

Next, a film forming apparatus used in the fabrication process from a copper forming step to a silicon nitride film forming step for the aforesaid semiconductor element will be explained using FIG. 1, FIG. 2 and FIG. 7. FIG. 1 is a plan view of the film forming apparatus, and FIG. 2 is a perspective view of reduced-pressure drying chambers constituting part of the film forming apparatus. FIG. 7 is a schematic sectional view of a CVD unit constituting part of the film forming apparatus.

A film forming apparatus 1 has a configuration in which a cassette station 2 for carrying, for example, 25 wafers W, as a unit, from/to the outside to/from the film forming apparatus 1 and for carrying the wafer W into/out of a cassette CR, and a processing station 3 for performing predetermined processing to the wafer W, are integrally united.

In the cassette station 2, a plurality of the cassettes CR are freely mounted at positions of positioning projections 10a on a cassette mounting table 10 in a line in an X-direction (a vertical direction in FIG. 1) with the respective ports for the wafer W facing the processing station 3 side. A first wafer carrier 11 movable in a direction of arrangement of the cassettes CR (the X-direction) and in a direction of arrangement of the wafers W housed in the cassette CR (a Z-direction; a vertical direction) is freely movable along a carrier guide 12 so as to selectively get access to each cassette CR.

The wafer carrier 11 is configured to be also rotatable in a θ-direction so as to get access to a wafer waiting portion 90 for delivering and receiving the wafer to/from a second carrier 81 in the processing station 3 described below and to a waiting chamber 50 of the processing station 3 described below.

In the processing station 3, the wafer waiting portion 90, a copper formation processing chamber 20, a CMP processing chamber 30, a cleaning processing chamber 120, reduced-pressure drying chambers 40a to 40c, the second carrier 81, CVD units 60 and 70 as film forming chambers, the waiting chamber 50 and a load-lock chamber 100 located along the transfer path of the wafer W from the reduced-pressure drying chambers 40a to 40c to the CVD chambers 60 and 70, are arranged.

The wafer waiting portion 90, the copper formation processing chamber 20, the CMP processing chamber 30, the cleaning processing chamber 120, and the reduced-pressure drying chambers 40a to 40c are respectively installed along the second carrier 81 to be able to access to the second carrier 81. The second carrier 81 is movable in a Y-direction and the Z-direction (the vertical direction), and is movable along a carrier guide 82.

Meanwhile, the CVD units 60 and 70, the reduced-pressure drying units 40a to 40c and the waiting chamber 50 are arranged to surround the load-lock chamber 100, and ascendable and descendable gate valves 111 to 114 enabling air-tightness are provided between the respective chambers to maintain reducecd-pressure states of the chambers. Further, ascendable and descendable gate valves 110 and 115 are provided respectively between the second carrier 81 and the reduced-pressure drying chambers 40a to 40c, and between the first carrier 11 and the waiting chamber 50. In the load-lock chamber 100, a third carrier 46 is installed which transfers the wafer from the reduced-pressure drying chambers 40a to 40c to the CVD units 60 and 70, and from the CVD units 60 and 70 to the waiting chamber 50.

The wafer waiting portion 90 is provided with four support pins 91 arranged so that the wafer W delivered from the first carrier 11 is held by the support pins 91. The wafer W held by the support pins 91 is taken out by the second carrier 81.

The copper formation processing chamber 20 is a processing chamber into which the wafer W carried in by the first carrier 11 and the second carrier 81 from the outside via the cassette station 2 is first carried. The copper formation processing chamber 20 has an opening 21, through which the wafer W is carried in/out, and the opening 21 is in a closed state by an ascendable and descendable gate shutter 131 while processing is performed in the copper formation processing chamber 20. The copper formation processing chamber 20 is provided with an annular cup CP at the center of the chamber bottom, and a spin chuck is disposed therein. The spin chuck is configured to rotate by a rotary driving force of a driving motor while fixedly holding the wafer W by vacuum-suction. The driving motor is disposed to be movable up and down by a cylinder, whereby the spin chuck is ascendable and descendable. Further, the copper formation processing chamber 20 is provided with a solution supply nozzle for supplying a copper material to the wafer surface of the wafer W. The formation of a copper film is performed by supplying the copper material to the front face with the wafer W rotated.

In the CMP processing chamber 30, the front face of the wafer W on which the copper film is formed in the copper formation processing chamber 20 is subjected to CMP (Chemical Mechanical Polishing) processing. The CMP processing chamber 30 has an opening 31, through which the wafer w is carried in/out, and the opening 31 is in a closed state by an ascendable and descendable gate shutter 132 while the processing is performed in the CMP processing chamber 30. The CMP processing chamber 30 is provided therein with a flat plate on which the wafer W is mounted and a rotatable large-diameter flat plate with a polishing cloth attached thereto which rotates pressing the polishing cloth against the front face of the wafer W mounted on the aforesaid flat plate. In the CMP processing, the front face of the wafer W is pressed against the polishing cloth with a fixed pressure and polished with a chemical abrasive called slurry containing abrasive grains such as alumina controlled in pH.

In the cleaning processing chamber 120, the wafer W which has been subjected to the CMP processing is cleaned, thereby performing processing of removing slurry and polished-away copper. The cleaning processing chamber 120 has an opening 121, through which the wafer W is carried in/out, and the opening 121 is in a closed state by an ascendable and descendable gate shutter 133 while the processing is performed in the cleaning processing chamber 120. The cleaning processing chamber 120 is provided with an annular cup CP at the center of the chamber bottom, and a spin chuck is disposed therein. The spin chuck is configured to rotate by a rotary driving force of a driving motor while fixedly holding the wafer W by vacuum-suction. The driving motor is disposed to be movable up and down by a cylinder, whereby the spin chuck is ascendable and descendable. Further, the cleaning processing chamber 120 is provided with a solution supply nozzle for supplying a cleaning solution, for example, pure water here to the wafer surface of the wafer W. The cleaning of the wafer W is performed by supplying the cleaning solution to the front face with the wafer W rotated.

The reduced-pressure drying chambers 40a to 40c are chambers each for drying the wafer W which has undergone the cleaning step, and are stacked one upon another as shown in FIG. 2. Each of the reduced-pressure drying chambers 40a to 40c is provided with a mounting plate 37 for mounting the wafer W thereon and four ascendable and descendable support pins 38 through the mounting plate 37. The support pins 38 ascend and receive, projecting from the mounting plate 37, the wafer W from the second carrier 81. The support pins 38 descend while supporting the wafer W to retract into the mounting plate 37, thereby mounting the wafer W on the mounting plate 37. The reduced-pressure drying chambers 40a to 40c are provided respectively with openings 41a to 41c through which access is possible to the second carrier 81 and openings 42a to 42c through which access is possible to the third carrier 46 in the load-lock chamber 100. The ascent of the gate valve 110 enables the delivery of the wafer W between the second carrier 81 and the reduced-pressure drying chambers 40a to 40c through the openings 41a to 41c, and the descent of the gate valve 110 causes the reduced-pressure drying chambers 40a to 40c to be tightly sealed. Further, the ascent of the gate valve 111 enables the delivery of the wafer W between the reduced-pressure drying chambers 40a to 40c and the load-lock chamber 100 through the openings 42a to 42c, and the descent of the gate valve 111 causes the reduced-pressure drying chambers 40a to 40c to be tightly sealed. An upper cavity chamber 39 is provided on top of the reduced-pressure drying chamber 40a, and a lower cavity chamber 43 beneath the reduced-pressure drying chamber 40c. The spaces in the cavity chambers and the reduced-pressure drying chambers are linked with each other through holes 37, 47, 48 and 49 which are provided respectively between the adjacent upper cavity chamber 39 and reduced-pressure drying chamber 40a, between the adjacent reduced-pressure drying chambers, and between the adjacent reduced-pressure drying chamber 40c and the lower cavity chamber 43. The inside of the spaces is always exhausted by an exhaust pipe 45 provided at the lower cavity chamber 43, and, further, an inert gas, for example, N₂ gas is always supplied thereto from a supply pipe 44 provided at the upper cavity chamber 39. This maintains the reduced-pressure drying chambers 40a to 40c under an N₂ gas atmosphere of 0.2 kPa. Further, the chamber temperature of the reduced-pressure drying chambers 40a to 40c is maintained at, for example, 23° C.

The load-lock chamber 100 is located along the transfer path of the wafer W from the reduced-pressure drying chambers 40a to 40c to the CVD units 60 and 70, and configured to be exhausted so that the inside thereof is maintained under a reduced-pressure state. The load-lock chamber 100 is provided therein with the third carrier 46. The third carrier 46 is of articulated arm type and has a base 46a, an intermediate arm 46b and a substrate support arm 46c which is provided at the tip thereof, in which the connections between them are turnable. The third carrier 46 delivers and receives the wafer W to/from the reduced-pressure drying chambers 40a to 40c, the CVD units 60 and 70 and the waiting chamber 50. The load-lock chamber 100 is always maintained under a reduced pressure of 66.5 Pa to 266 Pa, and N₂ gas is supplied into the chamber. As the inside of the reduced-pressure drying chambers 40a to 40c is under a reduced-pressure state, there occurs no reduced-pressure breakage when the load-lock chamber 100 receives the wafer W from the reduced-pressure drying chambers 40a to 40c with the inside thereof kept under the reduce-pressure state. Further, plasma CVD apparatus are used for the CVD units 60 and 70 described below in this embodiment, and the CVD units 60 and 70 are also kept under reduced-pressure states, whereby there occurs no reduced-pressure breakage when the wafer W is carried into/out of the CVD units 60 and 70 with the inside of the load-lock chamber 100 kept under the reduce-pressure state. Furthermore, the inside of the waiting chamber 50 described below can be set to be reduced in pressure, so that the waiting chamber 50 is brought to a reduced-pressure! state when the wafer W is carried out to the waiting chamber 50, thereby causing no reduced-pressure breakage with the load-lock chamber 100 kept under the reduced-pressure state.

Parallel plate plasma CVD apparatus are used respectively for the CVD units 60 and 70 which have the same structure. The CVD unit 60, as shown in FIG. 7, is composed of a vacuum chamber 161, a lower plate electrode 62 embedded therein with a heater 162 on which the wafer W is mounted and an upper plate electrode 163 which is disposed opposed to the lower plate electrode 62, an exhaust pipe 166 provided near the lower portion of the vacuum chamber 161 for exhausting the inside of the vacuum chamber 161, and a supply pipe 165 provided at the ceiling portion of the vacuum chamber 161 for supplying a film forming gas into the vacuum chamber 161. As shown in FIG. 1, three support pins 63 penetrating the lower plate electrode 62 to be ascendable and descendable. The support pins 63 ascend to project from the lower plate electrode 62 and hold the wafer W which is carried in by the third carrier 46 while keeping it away from the lower plate electrode 62. The support pins 63 descend to retract into the lower plate electrode 62, thereby mounting the wafer W on the lower plate electrode 62. The vacuum chamber 161 has an opening 61, so that the wafer W is carried in/out between the load-lock camber 100 and the CVD unit 60 through the opening 61 by the ascent of the gate valve 112, and the opening 61 is closed by the descent of the gate valve 112, bringing the inside of the CVD unit 60 into a tightly sealed state. In this embodiment, the formation of the silicon nitride film is performed under a reduced pressure of 13.3 Pa to 1330 Pa, and, for example, SiH₂Cl₂—NH₃ is used as the film forming gas.

The waiting chamber 50 is a place into which the wafer W which has been subjected to the film formation processing in the CVD unit 60 or 70 is temporarily carried by the third carrier. The waiting chamber 50 is provided with a mounting table 54 for mounting the wafer W thereon, four ascendable and descendable support pins 53 penetrating the mounting table 54, an exhaust pipe for exhausting the inside of the waiting chamber 50 to reduce pressure, and a valve which can be opened and closed for returning to the atmospheric pressure the inside of the waiting chamber 50 which is under a reduced pressure by the exhaust. The inside of the waiting chamber 50 is set under a reduced-pressure state when the wafer W is carried thereinto from the load-lock chamber 100, and is set under the atmospheric pressure when the wafer W is carried out of the loadlock chamber 100 by the first carrier 11. The waiting chamber 50 has openings 52 and 51, so that the ascent of the gate valve 114 allows the wafer W to be carried in/out between the load-lock chamber 100 and the waiting chamber 50 through the opening 52, and the ascent of the gate valve 115 allows the wafer W to be carried in/out between the waiting chamber 50 and the first carrier 11 through the opening 51.

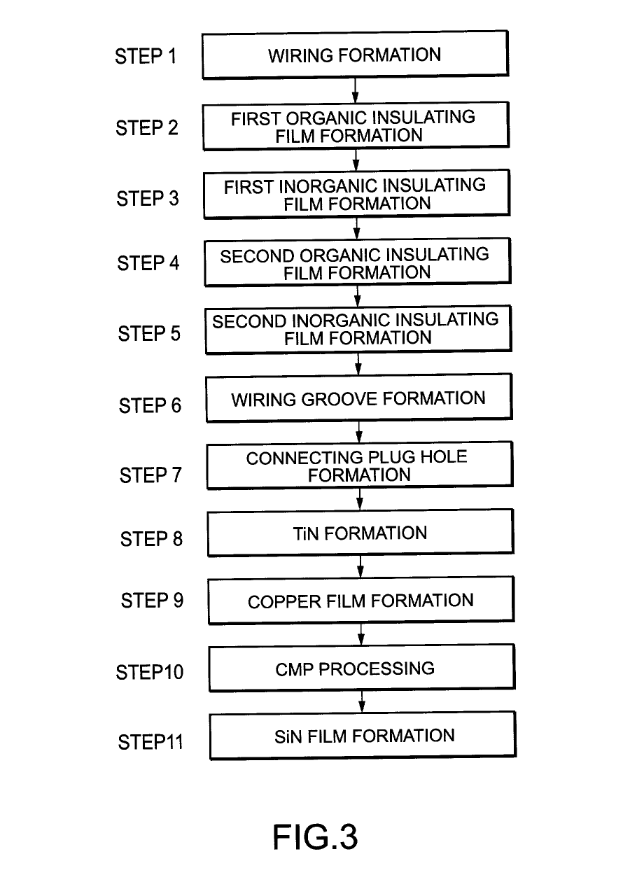

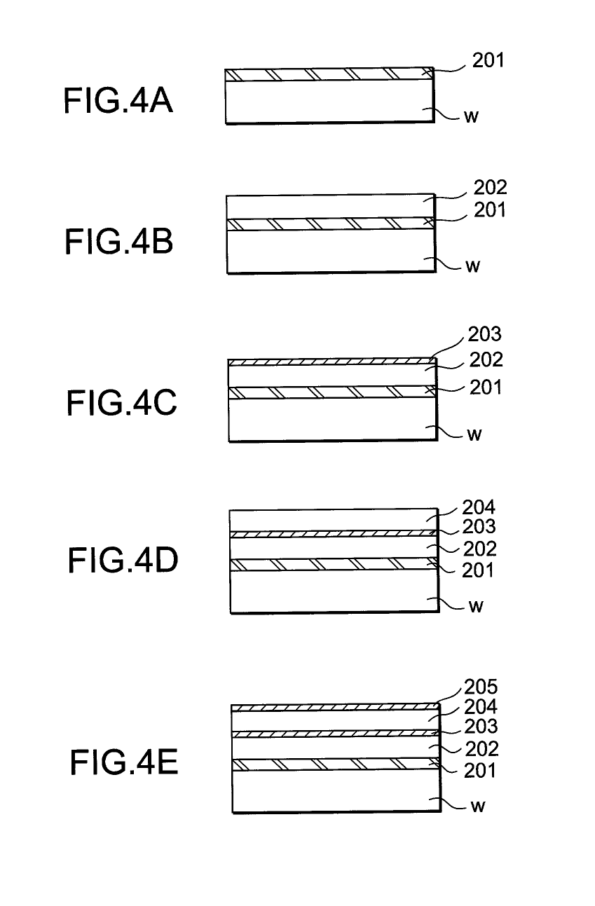

A fabrication method of a semiconductor element using the film forming apparatus having the above-described configuration will be explained next using FIG. 3 to FIG. 6. FIG. 3 is a chart for explaining fabrication process of a semiconductor element fabricated through a dual damascene process, FIGS. 4A to 4E through FIG. 6 are sectional views of the semiconductor element in processing steps explained in FIG. 3.

First, as shown in FIG. 4A, the lower layer wiring 201 made of SiO₂ is formed on the wafer W (step 1).

Then, as shown in FIG. 4B, after the wafer W is subjected to cooling processing to approximately 23° C., an organic insulating film material with a thickness of, for example, about 200 nm to about 500 nm, more preferably, approximately 300 nm is applied on the wafer W by spin coating to cover the lower layer wiring 201, thereby forming a first organic insulating film 202 (step 2). As the organic insulating film material, SILK is used here.

After the coating of the first organic insulating film, the wafer W is subjected to low-temperature heat processing, for example, at approximately 150° C. for about 60 seconds. Then, after the low-temperature heat processing, the wafer W is subjected to high-temperature heat processing, for example, at approximately 200° C. for about 60 seconds in a low-oxygen atmosphere. Further, the wafer W is subjected to high-temperature heat processing at approximately 350° C. for about 60 seconds in a low-oxygen atmosphere, for example, an oxygen atmosphere of 100 ppm. Furthermore, the wafer W is subjected to high-temperature heat processing at approximately 450° C. for about 60 seconds in a low-oxygen atmosphere and thereafter it is subjected to cooling processing at approximately 23° C.

As shown in FIG. 4C, an inorganic insulating film material with a thickness of, for example, about 300 nm to about 1100 nm, more preferably, approximately 700 nm is applied on the wafer W which has been subjected to the cooling processing to cover the first organic insulating film 202, thereby forming a first inorganic insulating film 203 (step 3). As the inorganic insulating film material, Nanoglass is used here.

After the formation of the first inorganic insulating film, the wafer W is carried into an aging processing unit and subjected to aging processing by (NH₃+H₂O) gas being introduced into the unit, whereby the inorganic insulating film material on the wafer W is gelatinized.

An exchange chemical solution is supplied onto the wafer W which has been subjected to the aging processing, whereby processing is performed in which a solvent in the insulating film applied on the wafer is exchanged for another solvent. Thereafter, the wafer W is subjected to low-temperature heat processing, for example, at approximately 175° C. for about 60 seconds.

The wafer W which has been subjected to the low-temperature heat processing is subjected to high-temperature heat processing, for example, at approximately 310° C. for about 60 seconds in a low-oxygen atmosphere, and, further, it is subjected to high-temperature heat processing, for example, at approximately 450° C. for 60 seconds in a low-oxygen atmosphere. Thereafter, the wafer W is subjected to cooling processing at approximately 23° C.

As shown in FIG. 4D, an organic insulating film material with a thickness of, for example, about 200 nm to about 500 nm, more preferably, approximately 300 nm is applied by spin coating on the wafer W which has been subjected to the cooling processing, thereby forming a second organic insulating film 204 (step 4). As the organic insulating film material, SILK is used here.

After the coating of the second organic insulating film, the wafer is subjected to low-temperature heat processing, for example, at approximately 150° C. for about 60 seconds. Then, after the low-temperature heat processing, the wafer W is subjected to high-temperature heat processing, for example, at approximately 200° C. for about 60 seconds in a low-oxygen atmosphere. Further, the wafer W is subjected to high-temperature heat processing at approximately 350° C. for about 60 seconds in a low-oxygen atmosphere, for example, an oxygen atmosphere of 100 ppm. Furthermore, the wafer W is subjected to high-temperature heat processing at approximately 450° C. for 60 seconds in a low-oxygen atmosphere and thereafter it is subjected to cooling processing at approximately 23° C.

As shown in FIG. 4E, an inorganic insulating film material with a thickness of, for example, about 300 nm to about 1100 nm, more preferably, approximately 700 nm is applied on the wafer W which has been subjected to the cooling processing to cover the second organic insulating film 204, thereby forming a second inorganic insulating film 205 (step 5). As the inorganic insulating film material, Nanoglass is used here.

After the formation of the second inorganic insulating film, the wafer W is carried into the aging processing unit and subjected to aging processing by (NH₃+H₂O) gas being introduced into the unit, whereby the inorganic insulating film material on the wafer W is gelatinized.

An exchange chemical solution is supplied onto the wafer W which has been subjected to the aging processing, whereby processing is performed in which a solvent in the insulating film applied on the wafer is exchanged for another solvent. Thereafter, the wafer W is subjected to low-temperature heat processing, for example, at approximately 175° C. for about 60 seconds.

The wafer W which has been subjected to the low-temperature heat processing is subjected to high-temperature heat processing, for example, at approximately 310° C. for about 60 seconds in a low-oxygen atmosphere, and, further, it is subjected to high-temperature heat processing, for example, at approximately 450° C. for 60 seconds in the low-oxygen atmosphere. Thereafter, the wafer W is subjected to cooling processing at approximately 23° C.

A resist film is formed on the second inorganic insulating film 205 of the wafer W which has been subjected to the cooling processing. For example, an acetal resist can be used as the resist film. After the formation of the resist film, heat and cooling processing is performed and predetermined exposure processing is performed in an aligner. The wafer W to which a pattern is exposed in the aligner is subjected to heat and cooling processing. Thereafter, developing processing is performed, whereby a resist pattern in a predetermined shape is formed. As the developing solution, TMAH (tetramethylammonium hydrooxide) is used here.

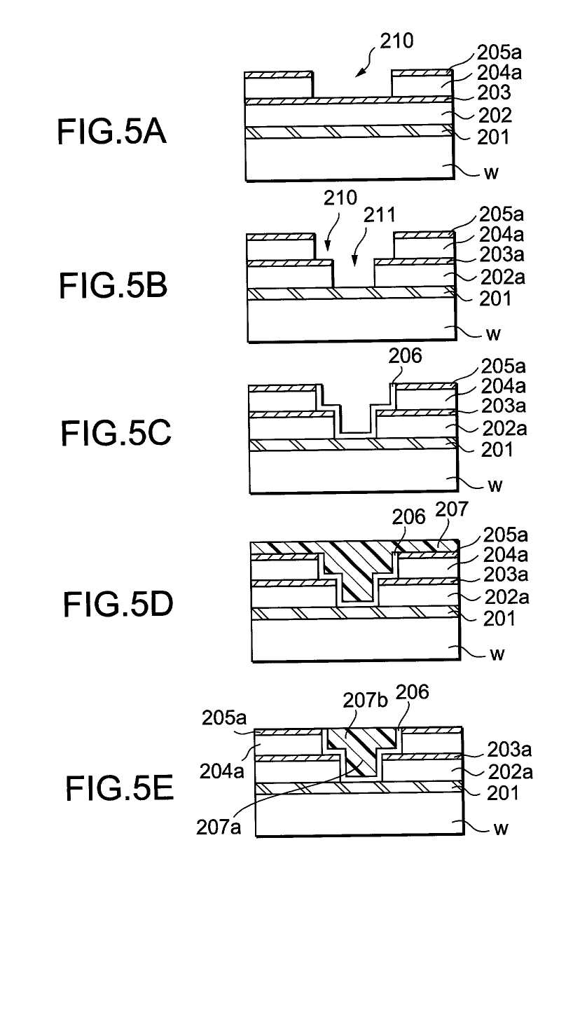

The wafer W for which the developing processing has been completed is subjected to heat and cooling processing. Thereafter, the second organic insulating film 204 and the second inorganic insulting film 205 are etched, as shown in FIG. 5A, by dry etching processing with the resist pattern as a mask by means of an etching unit. This enables the formation of the second organic insulating film pattern 204a and the second inorganic insulating film pattern 205a in which a recessed portion 210 corresponding to the wiring (step 6). The etching processing is performed here using, for example, CF₄ gas. After the etching processing, the resist pattern is removed.

Further, similarly through a resist pattern forming step, the first organic insulating film 202 and the first inorganic insulting film 203 are etched with the resist pattern as a mask, thereby forming the first organic insulating film pattern 202a and the first inorganic insulating film pattern 203a, as shown in FIG. 5B, in which a recessed portion 211 corresponding to the connecting plug is formed (step 7).

Thereafter, a side wall protecting titanium nitride (TiN) 206 for preventing diffusion of copper is formed by the plasma CVD unit on the side walls inside the recessed portion 210 corresponding to the wiring and the recessed portion 211 corresponding to the connecting plug as shown in FIG. 5c. As the side wall protecting film, Ti, TiW, Ta, TaN or WSiN can be used other than TiN (step 8).

The following fabrication process is executed using the above-described film forming apparatus 1, and thus the operation of the film forming apparatus 1 is additionally explained using FIG. 1, FIG. 2 and FIG. 7 as required.

The wafer W on which films up to the side wall protecting film layer 206 are formed is housed in the cassette CR mounted on the mounting table 10. On the cassette mounting table 10, an unprocessed wafer W is transferred, for example, from a wafer cassette CR1 through the wafer carrier 11 to the wafer waiting portion 90 on the processing station 3 side and held by the support pins 91. The wafer W held by the wafer waiting portion 90 is transferred by the second wafer carrier 81 through the opening 21 into the copper formation processing chamber 20.

The wafer W transferred into the processing chamber is securely held by vacuum suction by means of the spin chuck disposed in the cup CP. The copper material is supplied to the center of the wafer W with the wafer W rotated by the driving motor, thereby spreading the copper material over the front face of the wafer. This forms a copper film 207 on the wafer W as shown in FIG. 5D, embedding copper in the wiring recessed portion 210 and the connecting plug recessed portion 211 (step 9).

The wafer W formed with the copper film is taken out of the copper formation processing chamber 20 by the second carrier 81 and transferred into the CMP processing chamber 30 through the opening 31. The wafer W is mounted on the flat plate in the CMP processing chamber 30. Then, the large-diameter flat plate with the polishing cloth attached thereto is located in such a manner for the polishing cloth to contact the front face of the wafer W and is pressed with a fixed pressure, so that the front face of the wafer W is polished with the chemical abrasive called slurry containing abrasive grains such as alumina controlled in pH. This polishes away part of the copper on the front face of the second inorganic insulating film 205a which is not corresponding to the wiring recessed portion 210 nor the connecting plug recessed portion, copper remaining only inside the wiring recessed portion 210 and the connecting plug recessed portion 211, thereby forming the wiring 207b and the connecting plug 207a (step 10).

The wafer W which has been subjected to the CMP processing is taken out of the CMP processing chamber 30 by the second carrier 81 and transferred into the cleaning processing chamber 120 through the opening 121. The wafer W transferred into the cleaning processing chamber 120 is securely held by vacuum suction by means of the spin chuck disposed in the cup CP. The cleaning solution supply nozzle is moved while supplying the cleaning solution along the diameter of the wafer W which is being rotated by the driving motor, thereby supplying the cleaning solution over the front face of the wafer. This removes the slurry and the polished-away copper from the wafer W. After the cleaning, the wafer W is rotated with the supply of the cleaning solution from the solution supply nozzle stopped to thereby drain the solution. The CMP processing chamber and the cleaning processing chamber are arranged in the same film forming apparatus in this embodiment so that the wafer W is speedily transferred from the CMP processing chamber to the cleaning processing chamber, thus cleaning and removing the leavings produced in the CMP processing before cured. This fabricates a conforming semiconductor element with no leavings and the like attached.

The wafer W which has been subjected to the cleaning processing is taken out of the cleaning processing chamber 120 by the second carrier 81 and transferred to any of the reduced-pressure drying chambers 40a to 40c, for example, the reduced-pressure drying chamber 40a here through the opening 41a. In the reduced-pressure drying chamber 40a, the wafer W is mounted on the mounting plate 37, and then the gate valve 110 descends to tightly seal the inside of the reduced-pressure drying chamber, so that the inside of the chamber is brought into a reduced-pressure state of 0.2 kPa by exhausting air therein from the exhaust pipe 45. Incidentally, as the second carrier 81 is disposed in the atmospheric air, the inside of the reduced-pressure drying chamber is exposed in the atmospheric air when the wafer W is carried into the reduced-pressure drying chamber. The inside of the reduced-pressure drying chamber, however, is always exhausted from the exhaust pipe 45, and further N₂ gas is always supplied thereinto from the supply pipe 44, whereby the descent of the gate valve 110 quickly returns the inside of the reduced-pressure drying chamber into a desired reduced-pressure state, providing again a desired N₂ gas atmosphere. The wafer W is laid in the reduced-pressure drying chamber 40a for at least 40 seconds to 120 seconds under the reduced pressure, thereby performing drying after the cleaning. Further, the inside of the reduced-pressure drying chamber is reduced in pressure here to be brought into an inert gas atmosphere, whereby the inside of the reduced-pressure drying chamber is brought into a low-oxygen concentration state, thereby suppressing natural oxidization of copper.

The wafer W which has been dried under reduced pressure in the reduced-pressure drying chamber 40a is carried into the load-lock chamber 100 by the third carrier 46 in the load-lock chamber 100 through the opening 42a and an opening 101 which are produced by the ascent of the gate valve 111. While the gate valve 111 is in ascent, the gate valves 110, 112, 113, and 114 are in descent, whereby the openings corresponding thereto are closed by the respective gate valves. In the load-lock chamber 100 is always kept in a reduced-pressure state of 66.5 Pa to 266 Pa, so that the wafer is transferred from the reduced-pressure drying chamber 40a to the load-lock chamber 100 under the reduced-pressure state. When the wafer W is carried into the load-lock chamber 100, the gate valve 111 descends, closing the opening 101. The inside of the load-lock chamber 100 is reduced in pressure and in the inert gas atmosphere, so that the inside of the load-lock chamber 100 is in the low-oxygen concentration, thereby suppressing natural oxidization of copper.

Thereafter, the wafer W is carried into either the CVD unit 60 or 70, for example, the CVD unit 60 here. The transfer into the CVD unit 60 is performed through an opening 104 and the opening 61 produced by the ascent of the gate valve 112. The wafer W carried into the CVD unit 60 is laid on the lower plate electrode 62, and the gate valve 112 descends, closing the opening 61. The inside of the CVD unit 60 is supplied with SiH₂Cl₂NH₃ as a film forming gas from the supply pipe 165 under a reduced-pressure state of 13.3 Pa to 1330 Pa. A radio-frequency power is applied between the upper plate electrode 163 and the lower plate electrode 62 which are disposed to be opposed to each other, producing plasma of the film forming gas to form the silicon nitride (SiN) film 209 with a thickness of 50 nm to 150 nm on the wafer W as shown in FIG. 6 (step 12). This forms the semiconductor element 200. After the formation of the silicon nitride film, the gate valve 112 ascends, and the wafer W is taken out by the third wafer carrier 46 through the openings 61 and 104 and held in the load-lock chamber 100. Thereafter the gate valve 112 descends, closing the opening 104.

The wafer W held in the load-lock chamber 100 is transferred into the waiting unit 50 through the openings 103 and 52 produced by the ascent of the gate valve 114. In this event, the opening 51 of the waiting unit 50 is in a closed state by the descent of the gate valve 115, that is, the inside of the waiting unit 50 is previously in a reduced-pressure state with the valve closed.

After the wafer W is transferred to the waiting unit 50, the gate valve 114 descends, bringing the opening 52 into a closed state. The wafer W is mounted on the mounting table 54 in the waiting unit 50, and the valve is opened with the openings 52 and 51 closed, thereby bringing the inside of the waiting unit 50 into the atmospheric pressure state. At the point of time when the atmospheric pressure state is established, the wafer W is taken out by the first carrier 11 through the opening 51 produced by the ascent of the gate valve 115. The taken-out wafer W is housed in a collecting cassette CR2 disposed on the cassette mounting table 10 of the cassette station 2.

As described above, according to the film forming apparatus 1 and the film forming method of the present invention, the inside of the drying chamber in which the drying step after the cleaning is performed is reduced in pressure and brought into the inert gas atmosphere, so that the inside of the reduced-pressure drying chamber is in the low-oxygen concentration state, thereby suppressing natural oxidization of copper to obtain a semiconductor element of high quality.

Further, the second carrier 81 is installed under the atmospheric pressure in the above-described embodiment, but it may be installed under a reduced-pressure state. The installation under the reduced-pressure state can suppress more securely natural oxidization of copper while the wafer W is transferred from the CMP processing chamber to the reduced-pressure drying chamber.

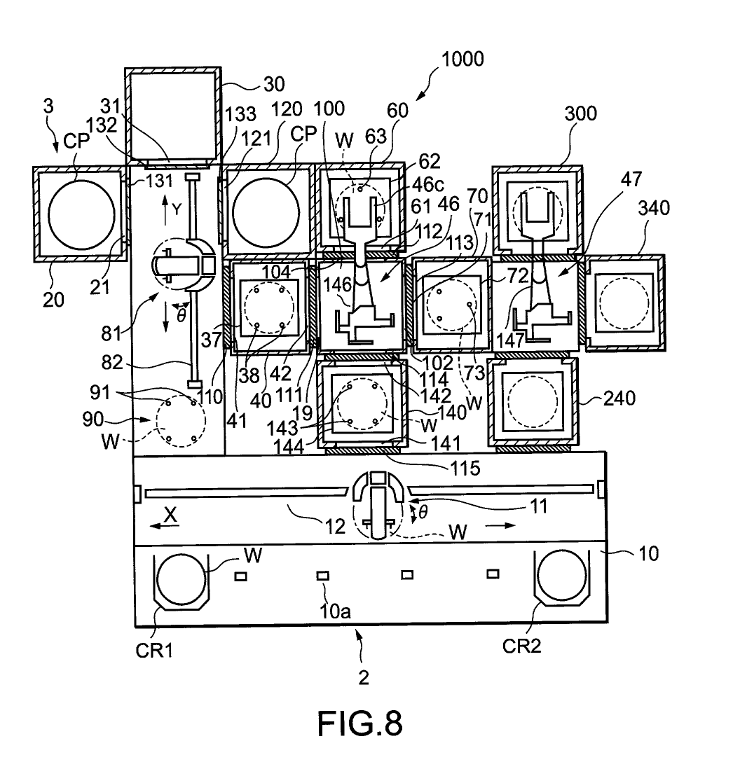

Next, another embodiment will be explained using FIG. 3 and FIG. 8.

FIG. 8 is a plan view showing a film forming apparatus of this embodiment. The film forming apparatus in FIG. 8 has almost the same configuration as that in FIG. 1, and thus only the points different from those in FIG. 1 will be explained.

In this embodiment, as shown in FIG. 8, a processing apparatus 1000 includes a processing station 3 which comprises a wafer waiting portion 90, a copper formation processing chamber 20, a CMP processing chamber 30, a cleaning processing chamber 120, CVD units 60 and 70 as film forming chambers, and additionally an etching unit 300 for forming a wiring groove, and a resist removing unit 340 for removing a resist after the formation of the wiring groove. Further, load-lock chambers 40, 140 and 240 are provided between the processing station 3 and at least one of a first carrier unit 12 and a second carrier unit 82.

In this embodiment, each load-lock chamber serves as a reduced-pressure drying chamber. However, it is unnecessary to cause the load-lock chamber to always function as the reduced-pressure drying chamber.

The load-lock chamber is configured so that the inside thereof can be exhausted, whereby it can be kept in a reduced-pressure state. Further, the inside of the load-lock chamber is maintained under a pressure of 66.5 Pa to 266 Pa with N₂ gas supplied thereinto.

Between each load-lock chamber and the processing chambers, a wafer carrier 46 or 47 as a vacuum delivery unit, in which an arm 146 or 147 is provided therein. These arms deliver the wafers W which have been dried in the load-lock chambers to the CVD units 60 and 70, the etching unit 300 and the resist removing unit (asher) 340.

Next, processing steps using the apparatus 1000 of this embodiment will be explained with reference to FIG. 3.

In this embodiment, steps after step 6 are performed in the apparatus 1000.

After the completion of the developing processing in an external apparatus, the wafer W is returned to the first carrier unit 12 and transferred through the load-lock chamber 240 and the wafer carrier 47 into the etching unit 300, where the wafer W is subjected to dry-etching processing with a resist pattern as a mask. Then, the wafer W is transferred via the carrier 47 into the resist removing unit 340, where the resist pattern is stripped, and then a second organic insulating film and a second inorganic insulating film are patterned (step 6). Thereafter, the wafer W which has temporarily been returned to the first carrier unit 12 through the load-lock chamber 240 is transferred to the external apparatus to be further formed with a resist pattern thereon. After the formation of the resist pattern, the wafer W is subjected to etching and resist removing as in the aforesaid steps and further to patterning of a first organic insulating film and a first inorganic insulating film (step 7).

Then, the plasma CVD unit forms a TiN film (step 8).

The wafer W on which films up to a side wall protecting film layer 206 are formed is transferred from the first carrier unit 12 through the second carrier unit 82 into the copper formation processing chamber 20 (step 9). After the formation of the copper film, the wafer W is transferred into the CMP processing chamber 30, where it is subjected to CMP processing (step 11). Then, the wafer W is transferred by the second carrier unit 82 into the cleaning processing chamber 120 to be cleaned.

The wafer W which has been subjected to the cleaning processing is transferred by the second carrier unit 82 from the cleaning processing chamber 120 to the load-lock chamber 40, where it is dried under reduced pressure.

The wafer W which has been dried under reduced pressure is carried through the wafer carrier 46 into the CVD unit 60 or 70, where plasma of the film forming gas is generated to form a SiN film on the wafer W (step 12). This forms a semiconductor element 200.

Although the copper forming step is performed by the spin coating method in the above-described embodiments, the film can also be formed by an electrolytic plating method, an electroless plating method, a CVD method or a sputtering method.

Further, the film forming chamber by the CVD method is provided in the above-described embodiments, but the layer insulating film can be formed by, for example, SOD (Spin-on-Dielectrics) method. In this case, an SOD processing chamber can be disposed in place of the copper formation processing chamber 20 in FIG. 1 and FIG. 8.

Furthermore, the first carrier unit and the second carrier unit are almost perpendicular to each other in the above-described embodiments, but a configuration having, for example, one of the carrier units is possible. In this case, the load-lock chamber (the reduced-pressure drying chamber) is arranged to exist between the processing chambers and the carrier unit.

Moreover, the explanation is given taking the semiconductor wafer as a substrate in the above-described embodiments, but the present invention is applicable to a substrate for a liquid crystal device. More specifically, the present invention can be applied to a case in which a substrate formed thereon with a film such as copper which is prone to oxidization is cleaned and dried, and then a film of some kind such as a silicon nitride film is formed on the oxidization-prone film. The drying step is performed under reduced pressure, and the transfer of the substrate between the drying step and the film forming step is performed under reduced pressure, thereby securely suppressing natural oxidization of the oxidization-prone film.

As described above, according to the present invention, in the case in which the substrate formed with the oxidization-prone film such as copper is cleaned and dried, and thereafter the insulating film such as a silicon nitride film is formed on the oxidization-prone film, the drying step is performed under reduced pressure, and the transfer of the substrate from the drying step to the film forming step is performed under reduced pressure, thereby securely suppressing natural oxidization of the oxidization-prone film.

The disclosure of Japanese Patent Application No.2000-146314 filed May 18, 2000 including specification, drawings and claims are herein incorporated by reference in its entirety.

Although only some exemplary embodiments of this invention have been described in detail above, those skilled in the art will readily appreciated that many modifications are possible in the exemplary embodiments without materially departing from the novel teachings and advantages of this invention. Accordingly, all such modifications are intended to be included within the scope of this invention.

What is claimed is:

1. A film forming apparatus, comprising:
a drying chamber for drying a cleaned substrate under a reduced pressure;
a film forming chamber for forming a film on the substrate by a CVD method under a reduced pressure; and
a transfer path for transferring the substrate under a reduced pressure from the drying chamber to the film forming chamber.

2. The apparatus as set forth in claim 1, further comprising:
a cleaning chamber for cleaning the substrate,
wherein the substrate cleaned in the cleaning chamber is dried under the reduced pressure in the drying chamber.

3. The apparatus as set forth in claim 2, further comprising:
a polishing chamber for polishing the substrate,
wherein the substrate processed in the polishing chamber is cleaned in the cleaning chamber.

4. The apparatus as set forth in claim 3,
wherein an oxidization-prone film is formed on the substrate.

5. The apparatus as set forth in claim 3, further comprising;
a conductive film forming chamber for forming a conductive film on the substrate formed with an insulating film having a recessed portion in a front face thereof to embed it in the recessed portion,
wherein the substrate formed with the conductive film in the conductive film forming chamber is polished in the polishing chamber so that the conductive film formed on the front face of the insulating film except for the recessed portion is polished away.

6. The apparatus as set forth in claim 5,
wherein the conductive film is made of copper.

7. The apparatus as set forth in claim 6,
wherein an inside of the drying chamber is in an inert gas atmosphere.

8. The apparatus as set forth in claim 7,
wherein a plurality of the drying chambers are provided.

9. A film forming method, comprising the steps of:
drying a cleaned substrate under a reduced pressure;
transferring the substrate with the reduced-pressure state kept after the reduced-pressure drying; and
forming a film on the substrate by a CVD method under a reduced pressure after the transfer.

10. The method as set forth in claim 9,
wherein an oxidization-prone film is formed on the substrate.

11. The method as set forth in claim 10,
wherein the oxidization-prone film is copper.

12. An apparatus, comprising:
a first substrate carrier for transferring a substrate in an atmospheric air;
a second substrate carrier provided almost perpendicular to the first substrate carrier for transferring the substrate in the atmospheric air; and
a processing chamber capable of delivering and receiving the substrate to/from at least one of the first substrate carrier and the second substrate carrier, for processing the substrate under a reduced pressure.

13. The apparatus as set forth in claim 12,
wherein the processing chamber is a CVD film forming chamber.

14. The apparatus as set forth in claim 12,
wherein the processing chamber is an etching processing chamber.

15. The apparatus as set forth in claim 12,
wherein the processing chamber is a resist removing chamber.

16. The apparatus as set forth in claim 12, further comprising:
a cleaning chamber for cleaning the substrate,
wherein the substrate cleaned in the cleaning chamber is dried under a reduced pressure in the processing chamber.

17. The apparatus as set forth in claim 12,
wherein the processing chamber is capable of delivering and receiving the substrate to/from the first substrate carrier, and
wherein the apparatus further comprises:
a polishing chamber, capable of delivering and receiving the substrate to/from the first substrate carrier, for polishing the substrate;
a cleaning chamber, capable of delivering and receiving the substrate to/from the first substrate carrier, for cleaning the substrate processed in the polishing chamber; and
a drying chamber, capable of delivering and receiving the substrate to/from the first substrate carrier, for drying under a reduced pressure the substrate cleaned in the cleaning chamber.

18. The apparatus as set forth in claim 17, further comprising:
a conductive film forming chamber, capable of delivering and receiving the substrate to/from the first substrate carrier, for forming a conductive film on the substrate formed with an insulating film having a recessed portion in a front face thereof to embed it in the recessed portion,
wherein the substrate formed with the conductive film in the conductive film forming chamber is polished in the polishing chamber so that the conductive film formed on the front face of the insulating film except for the recessed portion is polished away.

19. An apparatus, comprising:
a first substrate carrier for transferring a substrate in an atmospheric air;
a second substrate carrier for transferring the substrate under a reduced pressure; and
a third substrate carrier for transferring the substrate between the first substrate carrier and the second substrate carrier.

20. The apparatus as set forth in claim 19, further comprising:
a processing chamber, capable of delivering and receiving the substrate to/from the second substrate carrier, for processing the substrate under a reduced pressure.

21. The apparatus as set forth in claim 19, further comprising:
a polishing chamber, capable of delivering and receiving the substrate to/from the first substrate carrier, for polishing the substrate;
a cleaning chamber, capable of delivering and receiving the substrate to/from the first substrate carrier, for cleaning the substrate processed in the polishing chamber; and
a drying chamber, capable of delivering and receiving the substrate to/from the first substrate carrier, for drying under a reduced pressure the substrate cleaned in the cleaning chamber.

22. The apparatus as set forth in claim 19, further comprising:
a conductive film forming chamber, capable of delivering and receiving the substrate to/from the first substrate carrier, for forming a conductive film on the substrate formed with an insulating film having a recessed portion in a front face thereof to embed it in the recessed portion,
wherein the substrate formed with the conductive film in the conductive film forming chamber is polished in the polishing chamber so that the conductive film formed on the front face of the insulating film except for the recessed portion is polished away.
